(19) United States
(12) Patent Application Publication
(10) Pub. No.: US 2024/0079390 A1
(43) Pub. Date: Mar. 7, 2024

(54) DISPLAY DEVICE

(71) Applicant: LX SEMICON CO., LTD., Daejeon (KR)

(72) Inventor: Jung Hoon KIM, Daejeon (KR)

(73) Assignee: LX SEMICON CO., LTD., Daejeon (KR)

(21) Appl. No.: 18/461,623

(22) Filed: Sep. 6, 2023

(30) Foreign Application Priority Data
Sep. 6, 2022 (KR) 10-2022-0112575

(51) Int. Cl. H01L 25/075; H01L 25/16; H01L 33/30; H01L 33/40; H01L 33/62

(52) U.S. Cl. CPC H01L 25/0753; H01L 25/167; H01L 33/30; H01L 33/405; H01L 33/62

(57) ABSTRACT

Disclosed herein is a display device including at least one pixel, wherein the pixel includes a first micro light emitting element including a first region that emits first light and a second region that does not emit the first light, a second micro light emitting element that emits second light, and a third micro light emitting element that emits third light, and the second region at least partially overlaps the second and third micro light emitting elements on a plane.

This application claims the benefit of Korean Patent Application No. 10-2022-0112575, filed on Sep. 6, 2022, which is hereby incorporated by reference as if fully set forth herein.

### BACKGROUND OF THE DISCLOSURE

### Technical Field

The present disclosure relates to a display device.

### BACKGROUND

Liquid crystal display (LCD) and organic light emitting diode (OLED) displays have been widely used as display devices. Recently, a technology for manufacturing a high-resolution display device using micro-sized micro light emitting diodes (LEDs) has received considerable attention. A micro-LED display may be made by arranging hundreds of thousands of LEDs, which are micro light emitting elements having a size of, for example, 100 μm or less, on a substrate. Each micro-LED functions as a sub-pixel of the display and may have characteristics of high efficiency, high quality and high resolution compared to existing LCD or OLED displays.

In particular, in the case of a micro-LED, the luminous efficiency decreases as a chip size decreases. This phenomenon is due to sidewall etching damage that occurs when micro-LED sized chips are manufactured. Sidewall etching damage induces non-emissive bonding that prevents electron-hole pairs from combining normally.

### SUMMARY

Accordingly, the present disclosure is to directed to a high-density and ultra-small display device that corrects a difference in luminous efficiency for each color due to deviation of sidewall etching damage depending on emitted color of a micro light emitting element.

To achieve these objects and other advantages and in accordance with the purpose of the disclosure, as embodied and broadly described herein, a display device includes at least one pixel, wherein the pixel includes a first micro light emitting element including a first region that emits first light and a second region that does not emit the first light, a second micro light emitting element that emits second light, and a third micro light emitting element that emits third light, and the second region at least partially overlaps the second and third micro light emitting elements on a plane.

The display device according to an embodiment of the present disclosure may correct a difference in luminous efficiency due to deviation of sidewall etching damage depending on emitted color of a micro light emitting element.

The display device according to an embodiment of the present disclosure may realize high density, small size and high resolution.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a plan view of a display device according to an embodiment of the present disclosure;

FIG. 2A is a plan view of a pixel of a display device according to an embodiment of the present disclosure;

FIG. 2B is a plan view of a red micro light emitting element of FIG. 2A;

FIG. 3A is a block cross-sectional view taken along I-I′ of FIG. 2A;

FIG. 3B is a block cross-sectional view taken along II-IT of FIG. 2A;

FIG. 4A is another block cross-sectional view taken along I-I′ of FIG. 2A;

FIG. 4B is another block cross-sectional view taken along II-IT of FIG. 2A;

FIG. 5 is a cross-sectional view taken along I-I′ of FIG. 2A;

FIG. 6 is a cross-sectional view taken along II-IT of FIG. 2A;

FIG. 7A is a plan view of a pixel of a display device according to another embodiment of the present disclosure;

FIG. 7B is a plan view of a first micro light emitting element of FIG. 7A;

FIG. 8A is a plan view of a pixel of a display device according to another embodiment of the present disclosure; and

FIG. 8B is a plan view of a first micro light emitting element of FIG. 8A.

### DETAILED DESCRIPTION

Throughout the specification, like reference numerals are used to refer to substantially the same components. In the following description, detailed descriptions of components and features known in the art may be omitted if they are not relevant to the core configuration of the present disclosure. The meanings of terms used in this specification are to be understood as follows.

The advantages and features of the present disclosure, and methods of achieving them, will become apparent from the detailed description of the embodiments, together with the accompanying drawings. However, the present disclosure is not limited to the embodiments disclosed herein and will be implemented in many different forms. The embodiments are provided merely to make the disclosure of the present invention thorough and to fully inform one of ordinary skill in the art to which the present disclosure belongs of the scope of the invention. It is to be noted that the scope of the present disclosure is defined only by the claims.

The figures, dimensions, ratios, angles, numbers of elements given in the drawings are merely illustrative and are not limiting. Like reference numerals refer to like elements throughout the specification. Further, in describing the present disclosure, descriptions of well-known technologies may be omitted in order to avoid obscuring the gist of the present disclosure.

As used herein, the terms “includes,” “has,” “comprises,” and the like should not be construed as being restricted to the means listed thereafter unless specifically stated otherwise. Where an indefinite or definite article is used when referring to a singular noun e.g. “a” or “an”, “the”, this includes a plural of that noun unless something else is specifically stated.

Elements are to be interpreted as including a margin of error, even if not explicitly stated otherwise.

In describing temporal relationships, terms such as “after,” “subsequent to,” “next to,” “before,” and the like may include cases where any two events are not consecutive, unless the term “immediately” or “directly” is explicitly used.

While the terms first, second, and the like are used to describe various elements, the elements are not limited by these terms. These terms are used merely to distinguish one element from another. Accordingly, a first element referred to herein may be a second element within the technical idea of the present disclosure.

It should be understood that the term “at least one” includes all possible combinations of one or more related items. For example, the phrase “at least one of the first, second, and third items” can mean each of the first, second, or third items, as well as any possible combination of two or more of the first, second, and third items.

Features of various embodiments of the present disclosure can be partially or fully combined. As will be clearly appreciated by those skilled in the art, various interactions and operations are technically possible. Embodiments can be practiced independently of each other or in conjunction with each other.

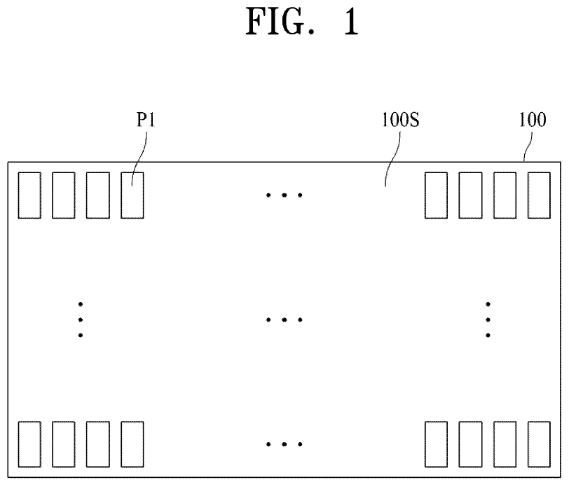

Hereinafter, with reference to FIGS. 1 to 6, a display device according to an embodiment of the present disclosure will be described in detail.

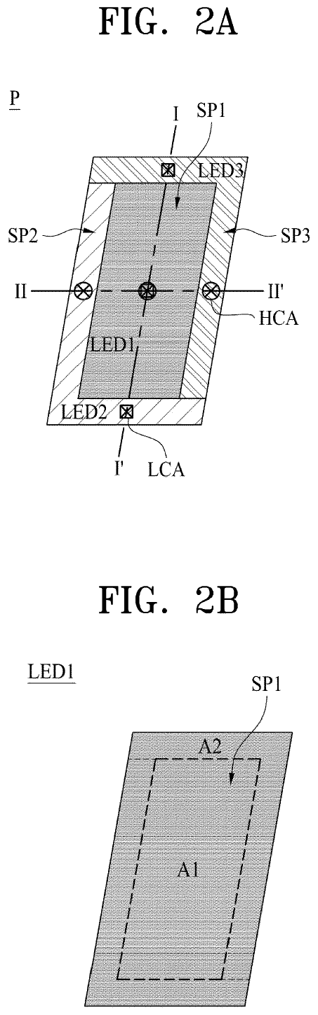

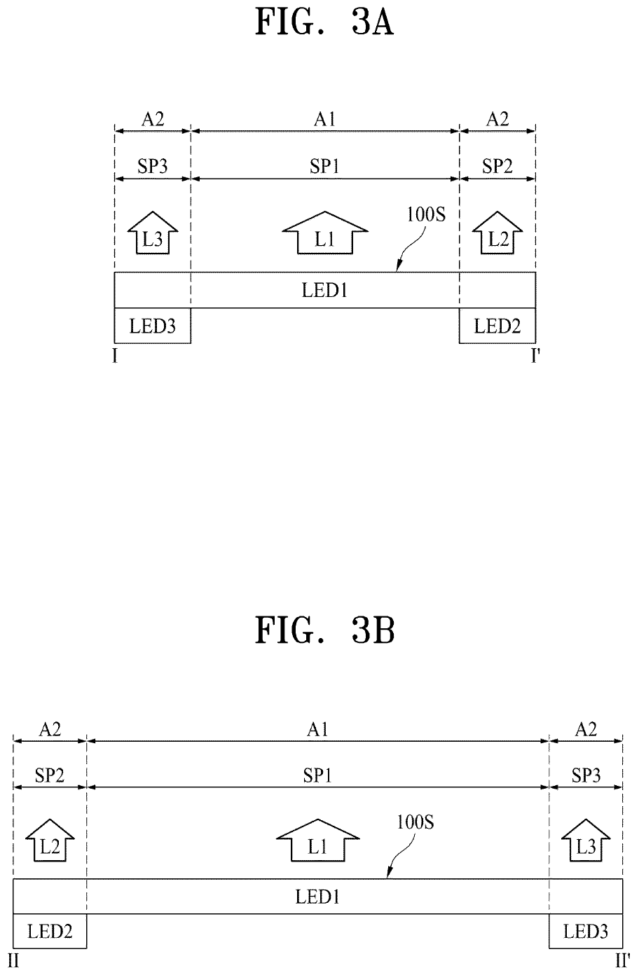

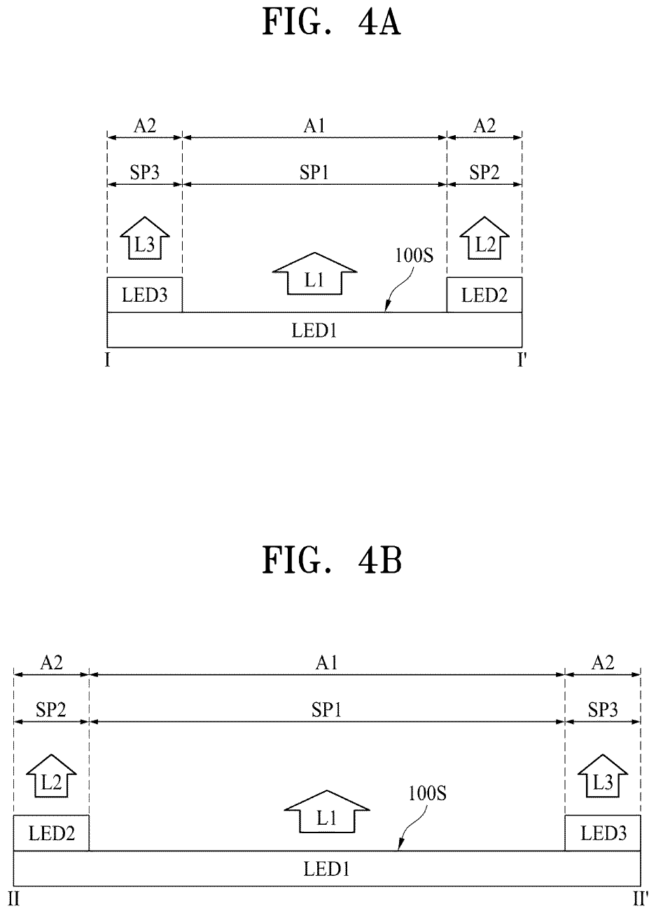

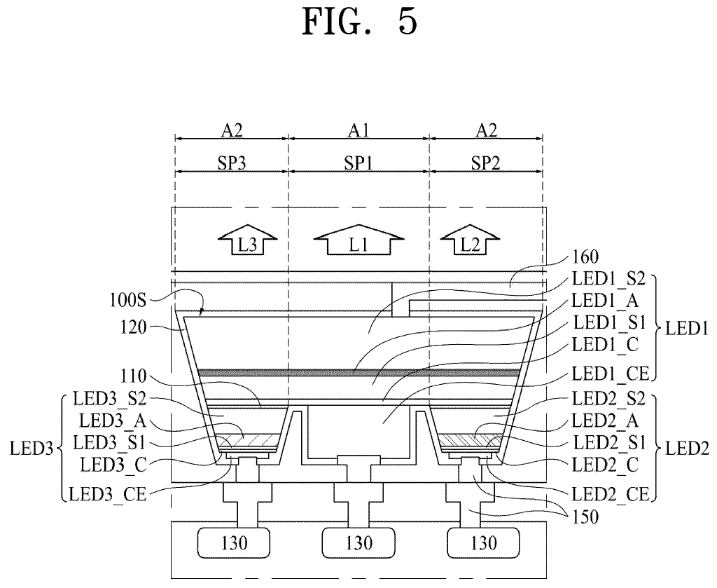

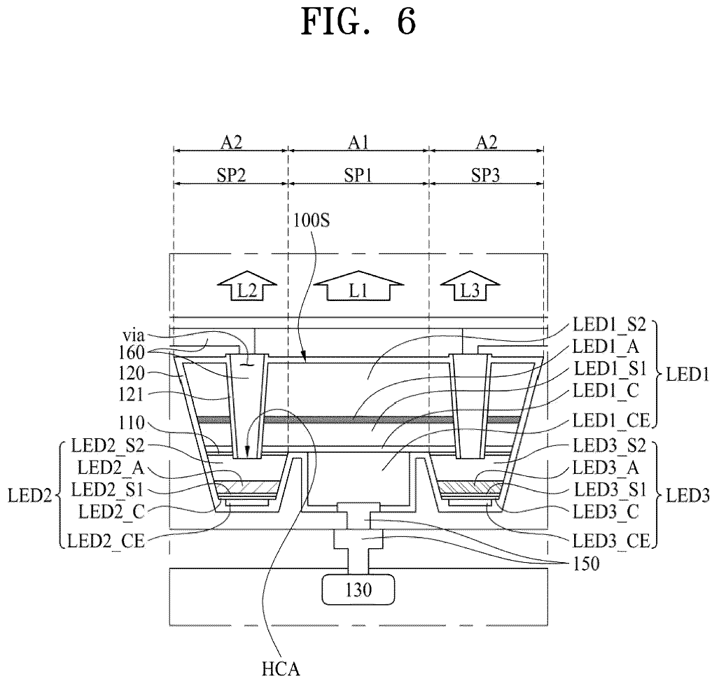

FIG. 1 is a plan view of a display device according to an embodiment of the present disclosure. FIG. 2A is a plan view of a pixel of a display device according to an embodiment of the present disclosure. FIG. 2B is a plan view of a red micro light emitting element of FIG. 2A. FIG. 3A is a block cross-sectional view taken along I-I′ of FIG. 2A. FIG. 3B is a block cross-sectional view taken along II-IT of FIG. 2A. FIG. 4A is another block cross-sectional view taken along I-I′ of FIG. 2A. FIG. 4B is another block cross-sectional view taken along II-IT of FIG. 2A. FIG. 5 is a cross-sectional view taken along I-I′ of FIG. 2A. FIG. 6 is a cross-sectional view taken along II-IT of FIG. 2A.

Referring to FIG. 1, a display 100 according to an embodiment of the present disclosure may include a plurality of pixels P uniformly distributed over a light exit surface 100s. Each pixel P may be defined as a region from which light is emitted by first to third micro light emitting elements LED1, LED2, and LED3, and each of the first to third micro light emitting elements LED1, LED2, and LED3 may be a micro light emitting element having a size of 200 μm or less, and for example, each of the first to third micro light emitting elements LED1, LED2, and LED3 may be an LED having a size of 95 μm or less. At this time, the size of each micro light emitting element may be a diameter in a given direction on a plane of a normally mounted micro light emitting element, and the given direction may be a horizontal direction or a vertical direction, or a direction having the maximum diameter on a plane.

Referring to FIG. 2A, each pixel P may include a first sub-pixel SP1, a second sub-pixel SP2, and a third sub-pixel SP3. The first sub-pixel SP1 may be defined as a region of the first micro light emitting element LED1, which emits light, the second sub-pixel SP2 may be defined as a region of the second micro light emitting element LED2, which emits light, and the third sub-pixel SP3 may be defined as a region of the third micro light emitting element LED3, which emits light. In this case, the light emitted from the first to third micro light emitting elements LED1, LED2, and LED3 may be light having different colors.

As shown in FIG. 2A, the pixel P may have a shape of a parallelogram, but is not limited thereto, and may have various shapes such as a rectangle, a rhombus, a polygon, or a circle.

The first micro light emitting element LED1 may include a first region A1 and a second region A2 on a plane. The first region A1 is defined as the first sub-pixel SP1 emitting first light. The second region A2 is a region that does not substantially emit the first light due to sidewall etching damage of the first micro light emitting element LED1. In detail, when the first micro light emitting element LED1 emits first light which is red, the first micro light emitting element LED1 may include a GaAs or AlGaInP-based semiconductor compound, and the GaAs or AlGaInP-based semiconductor compound may have a higher surface recombination velocity than the semiconductor compound included in the second micro light emitting element LED2 and the third micro light emitting element LED3, and thus non-emission recombination occurs in an edge region, and a region that does not emit light may be higher than in the second micro light emitting element LED2 and the third micro light emitting element LED3, and luminous efficiency may be lower than in the second micro light emitting element LED2 and the third micro light emitting element LED3. Accordingly, the second region A2 may include an edge region of the first micro light emitting element LED1 and may surround the first region A1 on a plane.

That is, the first region A1 may be a region emitting first light on a plane and defined as the first sub-pixel SP1 and, and the second region A2 may be a region that does not emit first light due to the aforementioned sidewall etching damage of the first micro light emitting element and may not be included in the first sub-pixel SP1. Accordingly, as shown in FIG. 2A, the first sub-pixel SP1 may have a smaller area than the first micro light emitting element LED1 on a plane.

The second micro light emitting element LED2 and the third micro light emitting element LED3 may be located in the second region A2 of the first micro light emitting element LED1. For example, as shown in FIG. 2A, the second micro light emitting element LED2 may be located in a left edge region and lower edge region of the first micro light emitting element LED1, and the third micro light emitting element LED3 may be located in a right edge region and upper edge region of the first micro light emitting element LED1. In this case, the second micro light emitting element LED2 and the third micro light emitting element LED3 may each have an L shape on a plane.

The second sub-pixel SP2 may have an area smaller than or substantially equal to that of the second micro light emitting element LED2 on a plane. The third sub-pixel SP3 may have an area smaller than or substantially equal to that of the third micro light emitting element LED3 on a plane.

Referring to FIGS. 3A to 4B, the first to third micro light emitting elements LED1, LED2, and LED3 respectively emit first light L1, second light L2, and third light L3 through the light exit surface 100s. In this case, the first light L1, the second light L2, and the third light L3 may emit light having different colors, and for example, the first light may be red light, the second light may be green light, and the third light may be blue light. However, the present disclosure is not limited thereto.

Referring to FIGS. 2A and 3A to 4B, the first micro light emitting element LED1 overlaps the second micro light emitting element LED2 and the third micro light emitting element LED3. In detail, the second region A2 of the first micro light emitting element LED1 at least partially overlaps the second micro light emitting element LED2 and the third micro light emitting element LED3. Accordingly, the second region A2 of the first micro light emitting element LED1 at least partially overlaps the second sub-pixel SP2 emitting the second light L2 and at least partially overlaps the third sub-pixel SP3 emitting third light.

As shown in FIGS. 3A and 3B, the first micro light emitting element LED1 may be located on the second micro light emitting element LED2 and the third micro light emitting element LED3, and the second light L2 emitted from the second micro light emitting element LED2 and the third light L3 emitted from the third micro light emitting element LED3 may be emitted from the light exit surface 100s through the first micro light emitting element LED1. In this case, the light exit surface 100s may be an exposed surface opposite to a surface of the first micro light emitting element LED1, on which the second and third micro light emitting elements LED2 and LED3 are located. However, the present disclosure is not limited thereto, and as shown in FIGS. 4A and 4B, the second micro light emitting element LED2 and the third micro light emitting element LED3 may be located on the first micro light emitting element LED1, and the second light L2 emitted from the second micro light emitting element LED2 and the third light L3 emitted from the third micro light emitting element LED3 may be emitted from the light exit surface 100s without going through the first micro light emitting element LED1. In this case, the light exit surface 100s may be an exposed surface of the first micro light emitting element LED1, on which the second and third micro light emitting elements LED2 and LED3 are located, and an exposed surface of the second and third micro light emitting elements LED2 and LED3.

In detail, as shown in FIGS. 5 and 6, each pixel P includes the first micro light emitting element LED1, the second micro light emitting element LED2, the third micro light emitting element LED3, an adhesive layer 110, a protective layer 120, an insulating layer 121, a driving circuit 130, a lower wiring 150, and an upper wiring 160.

The first micro light emitting element LED1 includes a lower contact electrode LED1_CE, a first semiconductor layer LED1_S1, an active layer LED1_A, and a second semiconductor layer LED1_S2.

The lower contact electrode LED1_CE of the first micro light emitting element is electrically connected to the first semiconductor layer LED1_S1 of the first micro light emitting element, a lower wiring to be described below, and a driving circuit to be described below.

The lower contact electrode LED1_CE of the first micro light emitting element may reflect light emitted from the first micro light emitting element LED1 in an opposite direction to the light exit surface 100s and emit the reflected light to the light exit surface 100s to improve luminous efficiency. To this end, the lower contact electrode LED1_CE of the first micro light emitting element may include a reflective material, for example, any one of structures of platinum (Pt) and gold (Au), nickel (Ni) and gold (Au), aluminum (Al), platinum (Pt), and gold (Au), and aluminum (Al), nickel (Ni), and gold (Au), or an alloy thereof.

In addition, the first micro light emitting element LED1 may further include a conductive layer LED1_C. The conductive layer LED1_C of the first micro light emitting element may be located between the lower contact electrode LED1_CE of the first micro light emitting element and the first semiconductor layer LED1_S1 of the first micro light emitting element, and thus the conductive layer LED1_C of the first micro light emitting element may improve the electrical characteristics of the first semiconductor layer LED1_S1 of the first micro light emitting element, and improve electrical contact with the lower contact electrode LED1_CE of the first micro light emitting element. The conductive layer LED1_C of the first micro light emitting element may be formed with a plurality of layers or patterns, and the conductive layer may be formed as a transparent electrode layer having transparency.

The conductive layer LED1_C of the first micro light emitting element may be formed to include at least one of, for example, indium tin oxide (ITO), indium zinc oxide (IZO), indium zinc tin oxide (IZTO), Indium aluminum zinc oxide (IAZO), Indium gallium zinc oxide (IGZO), indium gallium tin oxide (IGTO), aluminum zinc oxide (AZO), Antimony tin oxide (ATO), gallium zinc oxide (GZO), IZO nitride (IZON), Al—Ga ZnO (AGZO), In—Ga ZnO (IGZO), Zinc oxide (ZnO), iridium oxide (IrOx), ruthenium oxide (RuOx), nickel oxide (NiO), RuOx/ITO, and Ni/IrOx/gold (Au) but is not limited to these materials.

The first semiconductor layer LED1_S1, the active layer LED1_A, and the second semiconductor layer LED1_S2 of the first micro light emitting element may be sequentially stacked on the lower contact electrode LED1_CE and the conductive layer LED1_C of the first micro light emitting element.

The first semiconductor layer LED1_S1 and the second semiconductor layer LED1_S2 of the first micro light emitting element may be a conductivity type semiconductor layer. For example, each of the first semiconductor layer LED1_S1 and the second semiconductor layer LED1_S2 may be an n-type semiconductor layer or a p-type semiconductor layer. For example, when the first semiconductor layer LED1_S1 is a p-type semiconductor layer, the second semiconductor layer LED1_S2 may be an n-type semiconductor layer, and when the first semiconductor layer LED1_S1 is an n-type semiconductor layer, the second semiconductor layer LED1_S2 may be a p-type semiconductor layer.

When the first semiconductor layer LED1_S1 or the second semiconductor layer LED1_S2 of the first micro light emitting element is a p-type semiconductor layer, a dopant may be a p-type dopant such as Mg, Zn, Ca, Sr, or Ba. The first semiconductor layer LED1_S1 or the second semiconductor layer LED1_S2 of the first micro light emitting element may be formed as a single layer or multiple layers, but is not limited thereto. Alternatively, when the first semiconductor layer LED1_S1 or the second semiconductor layer LED1_S2 of the first micro light emitting element is an n-type semiconductor layer, the dopant may include an n-type dopant such as Si, Ge, Sn, Se, or Te. The first semiconductor layer LED1_S1 may be formed as a single layer or multilayer, but is not limited thereto.

The first semiconductor layer LED1_S1 or the second semiconductor layer LED1_S2 of the first micro light emitting element may be implemented as a compound semiconductor of a III-V group, a II-VI group, or the like, and may be doped with a p-type dopant or an n-type dopant. The first semiconductor layer LED1_S1 or the second semiconductor layer LED1_S2 may include a semiconductor material having a composition formula of AlxInyGa(1-x-y)N(0≤x≤1, 0≤y≤1, 0≤x+y≤1), any one or more of AlGaN, GaN, InAlGaN, AlGaAs, GaP, GaAs, GaAsP, and AlGaInP.

In particular, according to an embodiment of the present disclosure, the first micro light emitting element LED1 emits the first light L1, which is red, and thus the first semiconductor layer LED1_S1 and the second semiconductor layer LED1_S2 of the first micro light emitting element may include any one or more of a GaAs-based semiconductor compound or an AlGaInP-based semiconductor compound doped with a p-type dopant or an n-type dopant.

In this case, as the size of the first micro light emitting element LED1 decreases, the first micro light emitting element LED1 has a higher surface recombination velocity than a semiconductor compound included in first semiconductor layers LED2_S1 and LED3_S1 and second semiconductor layers LED2_S2 and LED3_S2 of the second micro light emitting element emitting the second light L2 which is green or the third micro light emitting element emitting the third light L3 which is blue, and thus non-emission recombination occurs in an edge region of the first micro light emitting element LED1, and a region that does not emit light may be higher than in the second micro light emitting element LED2 and the third micro light emitting element LED3, and luminous efficiency in the edge region of the first micro light emitting element LED1 is lower than in the second micro light emitting element LED2 and the third micro light emitting element LED3. According to an embodiment of the present disclosure, among regions in which the first micro light emitting element LED1 is located, a region that does not emit light due to sidewall etching damage may be classified as the second region A2, and the second region A2 may at least partially overlap the second micro light emitting element LED2 and the third micro light emitting element LED3.

The active layer LED1_A of the first micro light emitting element may be a layer that emits light by electron-hole recombination, may be located between the first semiconductor layer LED1_S1 and the second semiconductor layer of the first micro light emitting element, and may include any one of a double hetero structure, a multiple well structure, a single quantum well structure, a multi quantum well (MQW) structure, a quantum dot structure, or a quantum wire structure.

The active layer LED1_A of the first micro light emitting element includes a quantum well layer and a barrier layer, and is formed in one or more pair structures of a well layer and a barrier layer, for example, AlGaN/AlGaN, InGaN/GaN, InGaN/InGaN, AlGaN/GaN, InAlGaN/GaN, GaAs(InGaAs)/AlGaAs, and GaP(InGaP)/AlGaP using a III-V group compound semiconductor material, but is not limited thereto. The well layer may be formed of a material having an energy band gap smaller than that of the barrier layer.

The second micro light emitting element LED2 and the third micro light emitting element LED3 includes lower contact electrodes LED2_CE and LED3_CE, first semiconductor layers LED2_S1 and LED3_S1, active layers LED2_A and LED3_A, and second semiconductor layers LED2_S2 and LED3_S2 like the aforementioned first micro light emitting element LED1.

The lower contact electrode LED2_CE of the second micro light emitting element is electrically connected to the first semiconductor layer LED2_S1 and the driving circuit 130 of the second micro light emitting element, and the lower contact electrode LED3_CE of the third micro light emitting element is electrically connected to the first semiconductor layer LED3_S1 and the driving circuit 130 of the third micro light emitting element.

The lower contact electrodes LED2_CE and LED3_CE of the second and third micro light emitting elements may reflect the second light L2 and the third light L3 emitted in an opposite direction to a light exit surface from the second and third micro light emitting elements LED2 and LED3 to improve luminous efficiency. To this end, the lower contact electrodes LED2_CE and LED3_CE of second and third micro light emitting elements may include a reflective material, for example, any one of structures of platinum (Pt) and gold (Au), nickel (Ni) and gold (Au), aluminum (Al), platinum (Pt), and gold (Au), and aluminum (Al), nickel (Ni), and gold (Au), or an alloy thereof.

The first semiconductor layer LED2_S1, the active layer LED2_A, and the second semiconductor layer LED2_S2 of the second micro light emitting element may be sequentially stacked on the lower contact electrode LED2_CE and a conductive layer LED2_C 1 of the second micro light emitting element, and the first semiconductor layer LED3_S1, the active layer LED3_A, and the second semiconductor layer LED3_S2 of the third micro light emitting element may be sequentially stacked on the lower contact electrode LED3_CE and a conductive layer LED3_C 1 of the third micro light emitting element.

The first and second semiconductor layers LED2_S1 and LED2_S2 of the second micro light emitting element and the first and second semiconductor layers LED3_S1 and LED3_S2 of the third micro light emitting element may be a conductivity type semiconductor layer. For example, each of the first and second semiconductor layers LED2_S1 and LED2_S2 of the second micro light emitting element and the first and second semiconductor layers LED3_S1 and LED3_S2 of the third micro light emitting element may be an n-type semiconductor layer or a p-type semiconductor layer. When the first semiconductor layer LED2_S1 of the second micro light emitting element is a p-type semiconductor layer, the second semiconductor layer LED2_S2 of the second micro light emitting element may be an n-type semiconductor layer, and when the first semiconductor layer LED2_S1 of the second micro light emitting element is an n-type semiconductor layer, the second semiconductor layer LED2_S2 of the second micro light emitting element may be a p-type semiconductor layer. When the first semiconductor layer LED3_S1 of the third micro light emitting element is a p-type semiconductor layer, the second semiconductor layer LED3_S2 of the third micro light emitting element may be an n-type semiconductor layer, and when the first semiconductor layer LED3_S1 of the third micro light emitting element is an n-type semiconductor layer, the second semiconductor layer LED3_S2 of the third micro light emitting element may be a p-type semiconductor layer.

When the first and second semiconductor layers LED2_S1, LED2_S2, LED3_S1, and LED3_S2 of the second and third micro light emitting elements are a p-type semiconductor layer, a dopant may include a p-type dopant such as Mg, Zn, Ca, Sr, or Ba. The first and second semiconductor layers LED2_S1, LED2_S2, LED3_S1, and LED3_S2 of the second and third micro light emitting elements may be formed as a single layer or multiple layers, but are not limited thereto. In addition, when the first and second semiconductor layers LED2_S1, LED2_S2, LED3_S1, and LED3_S2 of the second and third micro light emitting elements are an n-type semiconductor layer, a dopant may include an n-type dopant such as Si, Ge, Sn, Se, or Te. The first and second semiconductor layers LED2_S1, LED2_S2, LED3_S1, and LED3_S2 of the second and third micro light emitting elements may be formed as a single layer or multiple layers, but are not limited thereto.

The first and second semiconductor layers LED2_S1 and LED2_S2 of the second micro light emitting element and the first and second semiconductor layers LED3_S1 and LED3_S2 of the third micro light emitting element may be implemented as a compound semiconductor of a III-V group, a II-VI group, or the like, and may be doped with a p-type dopant or an n-type dopant. The first and second semiconductor layers LED2_S1 and LED2_S2 of the second micro light emitting element and the first and second semiconductor layers LED3_S1 and LED3_S2 of the third micro light emitting element may include a semiconductor material having a composition formula of AlxInyGa(1-x-y)N(0≤x≤1, 0≤y≤1, 0≤x+y≤1), any one or more of AlGaN, GaN, InAlGaN, AlGaAs, GaP, GaAs, GaAsP, and AlGaInP.

In particular, according to an embodiment of the present disclosure, the second micro light emitting element LED2 emits the second light L2, which is green, and the third micro light emitting element LED3 emits the third light L3, which is blue, and thus the first and second semiconductor layers LED2_S1 and LED2_S2 of the second micro light emitting element and the first and second semiconductor layers LED3_S1 and LED3_S2 of the third micro light emitting element may each include any one or more of a GaInN-based semiconductor compound or a GaN-based semiconductor compound doped with a p-type dopant or an n-type dopant.

The active layers LED2_A and LED3_A of the second and third micro light emitting elements may be a layer that emits light by electron-hole recombination, may be located between the first semiconductor layers LED2_S1 and LED3_S1 of the second and third micro light emitting elements and the second semiconductor layers LED2_S2 and LED3_S2 of the second and third micro light emitting elements, and may include any one of a double hetero structure, a multiple well structure, a single quantum well structure, a multi quantum well (MQW) structure, a quantum dot structure, or a quantum wire structure.

The active layers LED2_A and LED3_A of the second and third micro light emitting elements include a quantum well layer and a barrier layer, and is formed in one or more pair structures of a well layer and a barrier layer, for example, AlGaN/AlGaN, InGaN/GaN, InGaN/InGaN, AlGaN/GaN, InAlGaN/GaN, GaAs(InGaAs)/AlGaAs, and GaP(InGaP)/AlGaP using a III-V group compound semiconductor material, but is not limited thereto. The well layer may be formed of a material having an energy band gap smaller than that of the barrier layer.

The pixel P includes an adhesive layer that adheres the second and third micro light emitting elements LED2 and LED3 to the first micro light emitting element LED1. In detail, the first to third micro light emitting elements LED1, LED2, and LED3 may separately be grown and manufactured from a growth substrate, and the separately manufactured second micro light emitting element LED2 and the third micro light emitting element LED3 may be attached to the first micro light emitting element LED1 to constitute one pixel. In this case, the second and third micro light emitting elements LED2 and LED3 may be attached to a surface of the first micro light emitting element LED1, which faces the light exit surface 100s. However, the present disclosure is not limited thereto, and the second and third micro light emitting elements LED2 and LED3 may also be attached to the light exit surface 100s of the first micro light emitting element LED1. In addition, according to an embodiment of the present disclosure, the separately manufactured second and third micro light emitting elements LED2 and LED3 may each be attached to the second region A2 of the first micro light emitting element LED1, which does not emit the first light L1 and may constitute one pixel P. In this case, the second and third micro light emitting elements LED2 and LED3 may not overlap each other and may be located on the same plane.

The pixel P may further include the protective layer 120 that protects the first micro light emitting element LED1 to which the second micro light emitting element LED2 and the third micro light emitting element LED3 are attached. The protective layer 120 may be formed to cover external surfaces of the first micro light emitting element LED1, the second micro light emitting element LED2, and the third micro light emitting element LED3. In this case, the protective layer 120 may be formed to cover the external surface of the first to third micro light emitting elements LED1, LED2, and LED3 except for a region in which each of the first to third micro light emitting elements LED1, LED2, and LED3 is connected to the upper wiring 160 and the lower wiring 150. The protective layer 120 may be made of a material such as SiO₂, Si₃N₄, or polyimide, and the protective layer 120 may include a material with high reflectance to increase the efficiency of light emitted from first to third micro light emitting elements LED1, LED2, and LED3, for example, a distributed Bragg reflector (DBR) structure.

The pixel P may include the driving circuit 130 that is connected to each of the first to third micro light emitting elements LED1, LED2, and LED3 and drives first to third sub-pixels SP1, SP2, and SP3. The driving circuit 130 may apply current to each of the first to third micro light emitting elements LED1, LED2, and LED3 through the lower contact electrodes LED1_CE, LED2_CE, and LED3_CE of the first to third micro light emitting elements LED1, LED2, and LED3. Thus, emission recombination of a carrier occurs in the active layers LED1_A, LED2_A, and LED3_A of the first to third micro light emitting elements, and the active layer emits light corresponding to band gap energy. In this case, the driving circuit 130 may have a multilayer structure, and for example, the driving circuit 130 may include a buffer layer, a gate insulating layer stacked on the buffer layer, an interlayer insulating layer stacked on the gate insulating layer, and a plurality of passivation layers that are sequentially stacked on the interlayer insulating layer.

The pixel P may include the lower wirings 150 connected to the lower contact electrodes LED1_CE, LED2_CE, and LED3_CE of the first to third micro light emitting elements. In detail, as shown in FIG. 6, the lower wirings 150 may be electrically connected to the driving circuit 130 located below the first to third micro light emitting elements LED1, LED2, and LED3 through a region of the lower contact electrodes LED1_CE, LED2_CE, and LED3_CE of the first to third micro light emitting elements, in which an insulation layer is not formed. In this case, the lower contact areas LCA in which the first to third micro light emitting elements LED1, LED2, and LED3 and the lower wiring 150 are electrically connected by direct contact may be spaced apart from each other by a certain distance or more to prevent shorting each other, as shown in FIG. 2A.

The pixel P may include the upper wiring 160 connected to the second semiconductor layers LED1_S2, LED2_S2, and LED3_S2 of the first to third micro light emitting elements. In detail, the upper wiring 160 may be electrically connected to the second semiconductor layers LED1_S2, LED2_S2, and LED3_S2 of the first to third micro light emitting elements through a region in which the protective layer 120 is not formed. In this case, higher contact areas HCA in which the first to third micro light emitting elements LED1, LED2, and LED3 and the upper wiring 160 are electrically connected to each other by direct contact may be spaced apart from each other by a certain distance or more to prevent shorting each other, as shown in FIG. 2A. In particular, according to an embodiment of the present disclosure, as shown in FIG. 6, in the higher contact areas HCA of the second and third micro light emitting elements LED2 and LED 3), a via hole may be formed by etching the first micro light emitting element LED1 and the adhesive layer 110, the second semiconductor layers LED2_S2 and LED3_S2 of the second and third micro light emitting elements may be exposed through the formed via hole, and the upper wiring 160 may be located in the via hole and may be electrically connected to the second semiconductor layers LED2_S2 and LED3_S2 of the second and third micro light emitting elements by direct contact.

According to an embodiment of the present disclosure, the insulating layer 121 may be disposed between the first micro light emitting element LED1 and the upper wiring 160 that is electrically connected to the second micro light emitting element LED2 or the third micro light emitting element LED3. In detail, as described above, the insulating layer 121 may be formed on a surface in which the via hole formed by etching the first micro light emitting element LED1 and the adhesive layer 110 is defined. That is, the insulating layer 121 may be located between the first micro light emitting element LED1 and the upper wiring 160 that is electrically connected to the second micro light emitting element LED2 or the third micro light emitting element LED3 to prevent shorting between the first micro light emitting element LED1 and the second micro light emitting element LED2 or the third micro light emitting element LED3. To this end, the insulating layer 121 may be made of an insulating material such as SiO₂, Si₃N₄, or polyimide. In this case, as shown in FIG. 6, the insulating layer 121 may be integrally formed with the protective layer 120 but the present disclosure is not limited thereto, and the insulating layer 121 may be separately formed from the protective layer 120.

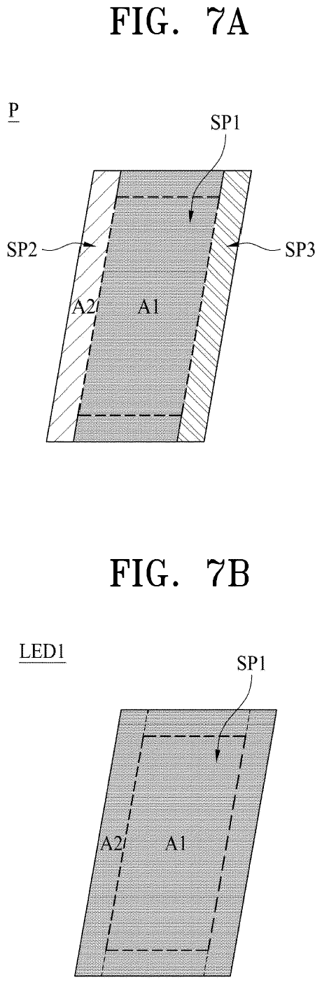

Hereinafter, with reference to FIGS. 7A and 7B, a pixel of a display device according to another embodiment of the present disclosure will be described in detail.

FIG. 7A is a plan view of a pixel of a display device according to another embodiment of the present disclosure. FIG. 7B is a plan view of the first micro light emitting element of FIG. 7A.

According to an embodiment of the present disclosure, as shown in FIGS. 7A and 7B, the first micro light emitting element LED1 may be located in an entire region of one pixel P on a plane.

The second micro light emitting element and the third micro light emitting element may be located in the second region A2 of the first micro light emitting element. For example, as shown in FIG. 7A, the second micro light emitting element may be located in a left edge region of the first micro light emitting element, and the third micro light emitting element may be located in a right edge region of the first micro light emitting element. In this case, the second micro light emitting element and the third micro light emitting element may each have a parallelogram shape on a plane.

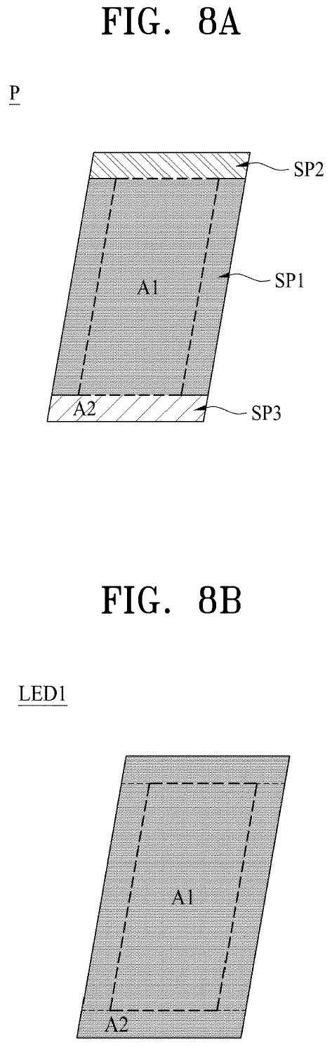

Hereinafter, with reference to FIGS. 8A and 8B, a pixel of a display device according to another embodiment of the present disclosure will be described in detail.

FIG. 8A is a plan view of a pixel of a display device according to another embodiment of the present disclosure. FIG. 8B is a plan view of a first micro light emitting element of FIG. 8A.

According to an embodiment of the present disclosure, as shown in FIGS. 8A and 8B, the first micro light emitting element may be located in an entire region of one pixel P on a plane.

The second micro light emitting element and the third micro light emitting element may located in the second region A2 of the first micro light emitting element. For example, as shown in FIG. 8A, the second micro light emitting element may be located in the lower edge region of the first micro light emitting element, and the third micro light emitting element may be located in the upper edge region of the first micro light emitting element. In this case, the second micro light emitting element and the third micro light emitting element may each have a parallelogram shape on a plane.

It will be appreciated by those skilled in the art to which the present disclosure belongs that the disclosure described above may be practiced in other specific forms without altering its technical ideas or essential features.

It should therefore be understood that the embodiments described above are exemplary and non-limiting in all respects. The scope of the present disclosure is defined by the appended claims, rather than by the detailed description above, and should be construed to cover all modifications or variations derived from the meaning and scope of the appended claims and the equivalents thereof.

What is claimed is:

1. A display device comprising:
at least one pixel,
wherein the pixel includes:
a first micro light emitting element including a first region that emits first light and a second region that does not emit the first light;
a second micro light emitting element that emits second light; and
a third micro light emitting element that emits third light,
wherein the second region at least partially overlaps the second and third micro light emitting elements on a plane.

2. The display device of claim 1, wherein the second region includes an edge region of the first micro light emitting element.

3. The display device of claim 1, wherein the pixel includes:
a first sub-pixel that emits the first light;
a second sub-pixel that emits the second light; and
a third sub-pixel that emits the third light,
wherein the first region defines the first sub-pixel, and
wherein the second region at least partially overlaps the second sub-pixel and at least partially overlaps the third sub-pixel.

4. The display device of claim 1, wherein the first micro light emitting element is located on the second micro light emitting element and the third micro light emitting element, and
wherein the second light and the third light are transmitted through the second region and are emitted to a light exit surface.

5. The display device of claim 4, wherein the light exit surface is an exposed surface of the first micro light emitting element, on which the second micro light emitting element and the third micro light emitting element are located.

6. The display device of claim 4, wherein the first micro light emitting element includes:
a lower contact electrode electrically connected to a driving circuit configured to drive the pixel, through a lower wiring; and
a first semiconductor layer, an active layer, and a second semiconductor layer stacked on the lower contact electrode,
wherein the lower contact electrode includes a reflective material.

7. The display device of claim 1, wherein the second micro light emitting element and the third micro light emitting element are located to overlap an edge region of the first micro light emitting element on the first micro light emitting element,
wherein the second light and the third light are emitted to a light exit surface, and
wherein the light exit surface is an exposed surface of the first micro light emitting element, on which the second micro light emitting element and the third micro light emitting element are located, an exposed surface of the second micro light emitting element, and an exposed surface of the third micro light emitting element.

8. The display device of claim 1, wherein each of the first to third micro light emitting elements includes:
a lower contact electrode electrically connected to a driving circuit configured to drive the pixel, through a lower wiring; and
a first semiconductor layer, an active layer, and a second semiconductor layer stacked on the lower contact electrode,
wherein the lower contact electrode includes a reflective material.

9. The display device of claim 1, wherein the first light is red light, the second light is green light, and the third light is blue light;
wherein each of the first to third micro light emitting elements includes:
a lower contact electrode electrically connected to a driving circuit configured to drive the pixel, through a lower wiring; and
a first semiconductor layer, an active layer, and a second semiconductor layer stacked on the lower contact electrode,
wherein the first micro light emitting element includes any one or more of a GaAs-based semiconductor compound or an AlGaInP-based semiconductor compound, and
wherein the second micro light emitting element and the third micro light emitting element includes any one or more of a GaInN-based semiconductor compound or a GaN-based semiconductor compound.

10. The display device of claim 1, wherein the second region is formed to surround the first region on a plane.

11. The display device of claim 1, wherein the pixel includes:
a first sub-pixel that emits the first light;
a second sub-pixel that emits the second light; and
a third sub-pixel that emits the third light,
wherein the first sub-pixel has a smaller area than the first micro light emitting element on a plane, and
wherein each of the second sub-pixel and the third sub-pixel has an area smaller than or substantially equal to an area of the second micro light emitting element and the third micro light emitting element on a plane.

12. The display device of claim 1, wherein the second micro light emitting element is attached to the second region of the first micro light emitting element through an adhesive layer,
wherein the third micro light emitting element is attached to the second region of the first micro light emitting element through an adhesive layer, and
wherein the second micro light emitting element is located on the same plane as the third micro light emitting element.

13. The display device of claim 1, further comprising:
an upper wiring electrically connected to the first to third micro light emitting elements on the first to third micro light emitting elements,
wherein each of the first to third micro light emitting elements includes a first semiconductor layer, an active layer, and a second semiconductor layer that are sequentially stacked,
wherein the second and third micro light emitting elements are exposed through a via hole formed by etching the first micro light emitting element in an upper contact area in which the second semiconductor layers of the second and third micro light emitting elements and the upper wiring are in direct contact, and
wherein the upper wiring is located in the via hole and is in direct contact with the second semiconductor layers of the second and third micro light emitting elements.

14. The display device of claim 13, further comprising:
an insulating layer located between the upper wiring located in the via hole and the first micro light emitting element.

15. The display device of claim 1, wherein the first micro light emitting element has a parallelogram shape on a plane, and
wherein each of the second micro light emitting element and the third micro light emitting element has an L shape on a plane.

16. The display device of claim 1, wherein each of the second micro light emitting element and the third micro light emitting element has a parallelogram shape on a plane.

17. A display device comprising:
at least one pixel,
wherein the pixel includes:
a first micro light emitting element that emits first light; and
a second micro light emitting element that emits second light, and
wherein the second micro light emitting element overlaps an edge region of the first micro light emitting element on a plane.

18. The display device of claim 17, wherein the second light is transmitted through the edge region of the first micro light emitting element and is emitted to a light exit surface.

19. The display device of claim 17, wherein the pixel includes:
a first sub-pixel that emits the first light; and
a second sub-pixel that emits the second light,
wherein the first sub-pixel has a smaller area than the first micro light emitting element on a plane, and
wherein the second sub-pixel has an area smaller than or substantially equal to an area of the second micro light emitting element on a plane.
